(19) United States
(12) Patent Application Publication
(10) Pub. No.: US 2007/0085224 A1
(43) Pub. Date: Apr. 19, 2007

(54) Semiconductor device having strong adhesion between wiring and protective film, and manufacturing method therefor

(75) Inventors: Ichiro Kouno, Tokyo (JP); Osamu Okada, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 11/524,455

(22) Filed: Sep. 20, 2006

(30) Foreign Application Priority Data
Sep. 22, 2005 (JP) 2005-275631

(51) Int. Cl. H01L 21/00; H01L 23/29

(52) U.S. Cl. 257/791; 438/106

(57) ABSTRACT

A semiconductor device has a semiconductor substrate having a plurality of connection pads on an upper surface thereof, a protective film made of a resin which is provided on the semiconductor substrate, and has openings at those portions to which the respective connection pads correspond, an altered layer having a mesh-like structure formed on an upper surface of the protective film, and a metallic layer provided on upper surfaces of the connection pads and an upper surfaces of the altered layer.

### BACKGROUND OF THE INVENTION

1. Field of the Invention

The present invention relates to a semiconductor device having high adhesion between a wiring and a protective film and a manufacturing method therefor.

2. Description of the Related Art

In semiconductor devices having a semiconductor chip directly mounted on the connection pad of a circuit board by flip chip bonding or face down bonding, a bump electrode made of gold, copper or the like is formed on an external connection pad for wirings connected to an integrated circuit formed on the upper surface of a semiconductor substrate. To form the bump electrode, a metallic base layer so-called barrier layer or bonding layer is laid out between the external connection pad and the bump electrode for preventing diffusion therebetween and enhancing bonding power therebetween. The metallic base layer is generally formed by vapor deposition or sputtering. In forming this layer, if a native oxide is formed on the upper surface of the external connection pad formed on the semiconductor substrate, adhesion decreases and oxidation will further progress, thereby lowering the reliability of a junction. Accordingly, the native oxide is eliminated by dry etching in a pressure reduced atmosphere containing inactive ions. In a case where a protective film of polyimide having an opening for exposing the external connection pad is formed on the upper surface of the semiconductor substrate, a process of eliminating the native oxide changes the property of the upper surface layer of the protective film of polyimide, so that the insulation resistance of the upper surface layer of the protective film of polyimide decreases. This increases a leak current between the bump electrodes formed after the elimination process, and in the extreme, causes short-circuiting between the bump electrodes.

U.S. Pat. No. 5,538,920 granted to the present applicant discloses a countermeasure to solve the aforementioned problem. A semiconductor device manufacturing method disclosed in this patent publication eliminates an altered layer formed on the upper surface of the protective film by oxygen plasma etching after the metallic base layer and the bump electrodes are formed. Accordingly, the upper surface layer of an insulation layer between the bump electrodes has a high resistance which can completely eliminate the occurrence of a leak current and short-circuiting

When an opening is formed in the polyimide protective film, a polyimide residue so-called scum may remain on the upper surface of the external connection pad exposed through the opening of the protective film. The residue is eliminated by oxygen plasma etching. In this case, oxygen plasmas change the property of the upper surface layer of the polyimide protective film, thereby forming an altered layer (this layer is hereinafter called “altered layer A”).

Subsequently, argon ion etching is performed to eliminate the native oxide formed on the upper surface of the external connection pad exposed through the openings of the insulation film and the protective film, but if this etching is of an ion gun type, the altered layer A on the protective film further changes its property, forming another altered layer (this layer is hereinafter called “altered layer B”). However, as will be discussed later, the altered layer B has weak adhesion to the metallic base layer, so that separation is likely to occur at the interface therebetween.

Thus, an object of the present invention is to provide a semiconductor device and a manufacturing method thereof that can enhance adhesion of an altered layer, which is formed on the upper surface side of a protective film, to a metallic base layer.

### SUMMARY OF THE INVENTION

To achieve the object, a semiconductor device of the invention comprises a semiconductor substrate having a plurality of connection pads on an upper surface thereof, a protective film made of a resin which is provided on the semiconductor substrate, and has openings at those portions to which the respective connection pads correspond; an altered layer having a mesh-like structure formed on an upper surface of the protective film; and a metallic layer provided on upper surfaces of the connection pads and an upper surfaces of the altered layer.

A semiconductor device manufacturing method of the invention comprises: a step of forming a protective film made of a resin on a semiconductor substrate having a plurality of connection pads on an upper surface thereof in such a way that the protective film has openings at those portions to which the connection pads correspond; a protective film residue elimination step of eliminating a residue of the protective film remaining on upper surfaces of the connection pads exposed through the openings of the protective film by an oxygen plasma ashing; an oxide film elimination step of eliminating an oxide film formed on the upper surfaces of the connection pads exposed through the openings of the protective film by a plasma etching with an inert gas; a metallic film formation step of forming a metallic film on the upper surfaces of the connection pads exposed through the openings of the protective film and an upper surface of the protective film; and a protective film upper surface layer elimination step of eliminating an upper surface layer of the protective film in an area other than an area underlying the metallic layer by an oxygen plasma ashing, and wherein a first altered layer formed on the upper surface of the protective film in the protective film residue elimination step is altered to a second altered layer having a larger surface roughness than that of the first altered layer in the oxide film elimination step, thereby improving reduced adhesion between the metallic film formed on the second altered layer formed on the upper surface of the protective film in the metallic film formation step and the protective film.

### BRIEF DESCRIPTION OF THE DRAWINGS

These objects and other objects and advantages of the present invention will become more apparent upon reading of the following detailed description and the accompanying drawings in which:

FIG. 1 is a cross-sectional view illustrating an embodiment of a semiconductor device according to the invention;

FIG. 2 is a cross-sectional view illustrating a silicon substrate prepared at first in an example of a manufacturing method for the semiconductor device illustrated in FIG. 1;

FIG. 3 is a cross-sectional view illustrating a process following a process illustrated in FIG. 2;

FIG. 4 is a cross-sectional view illustrating a process following the process illustrated in FIG. 3;

FIG. 5 is a cross-sectional view illustrating a process following the process illustrated in FIG. 4;

FIG. 6 is a cross-sectional view illustrating a process following the process illustrated in FIG. 5;

FIG. 7 is a cross-sectional view illustrating a process following the process illustrated in FIG. 6;

FIG. 8 is a cross-sectional view illustrating a process following the process illustrated in FIG. 7;

FIG. 9 is a cross-sectional view illustrating a process following the process illustrated in FIG. 8;

FIG. 10 is a cross-sectional view illustrating a process following the process illustrated in FIG. 9;

FIG. 11 is a cross-sectional view illustrating a process following the process illustrated in FIG. 10;

FIGS. 12A, 12B, 12C and 12D are diagrams illustrating SEM photographs of a protective film, an altered layer A, an altered layer C, and an altered layer B, respectively; and

FIG. 13 is a perspective view illustrating a device of the invention applied to a shear strength test.

### DETAILED DESCRIPTION OF THE PREFERRED EMBODIMENT

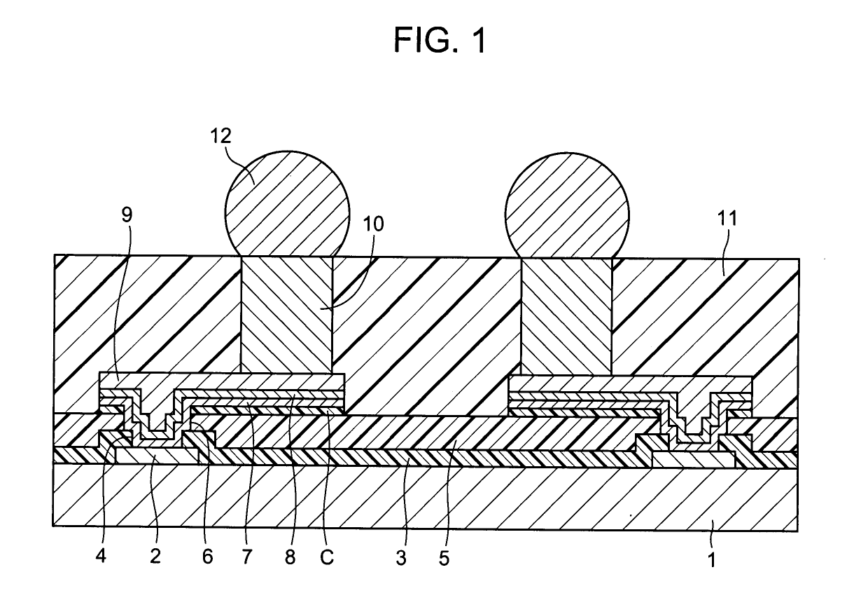

FIG. 1 is a cross-sectional view illustrating a semiconductor device according to an embodiment of the invention. The semiconductor device is generally called CSP (Chip Size Package), and has a silicon substrate (semiconductor substrate) 1. An integrated circuit (not shown) having a predetermined function is provided on the upper surface of the silicon substrate 1. A plurality of connection pads 2 made of aluminum, aluminum alloy, or aluminum-based metal are provided on the periphery portions of the upper surface of the silicon substrate 1 in such a manner as to be connected to the integrated circuit.

An insulation film 3 made of an inorganic material, such as silicon oxide, silicon nitride, or TEOS, is provided on the upper surface of the silicon substrate 1 excluding the central portions of the connection pads 2. The central portions of the connection pads 2 are exposed through openings 4 formed in the insulation film 3. A protective film 5 made of an organic material, such as polyimide or polybenzo-oxide (PBO), is provided on the upper surface of the insulation film 3. In this case, on the upper surface side of the protective film 5, as will be discussed later, formed under a first metallic base layer 7 to be discussed later by patterning is an altered layer changed from the material of the protective film 5 (this altered layer is hereinafter called altered layer C). Openings 6 slightly larger than the openings 4 of the insulation film 3 are formed in those portions of the protective film 5 including the altered layer C which correspond to the openings 4 of the insulation film 3.

The first metallic base layer 7 made of titanium, chrome, or the like is provided on the interiors of the openings 4 of the insulation film 3, the interiors of the openings 6 of the protective film 5 including the altered layer C, and the entire upper surface of the altered layer C. A second metallic base layer 8 made of copper is provided on the entire upper surface of the first metallic base layer 7. A wiring 9 made of copper is provided on the entire upper surface of the second metallic base layer 8. One end portion of the wiring 9 including the first and second metallic base layers 7, 8 is connected to the connection pad 2 through the opening 4 of the insulation film 3 and the opening 6 of the protective film 5 including the altered layer C.

Copper columnar electrodes 10 are provided on the upper surface of the connection pad portions of the wiring 9. A sealing film 11 made of an epoxy-based resin or a phenol-based resin is provided on the upper surface of the protective film 5 including the wiring 9 in such a way that the upper surface of the sealing film 11 is level with the upper surfaces of the columnar electrodes 10. Solder balls 12 are provided on the upper surfaces of the columnar electrodes 10.

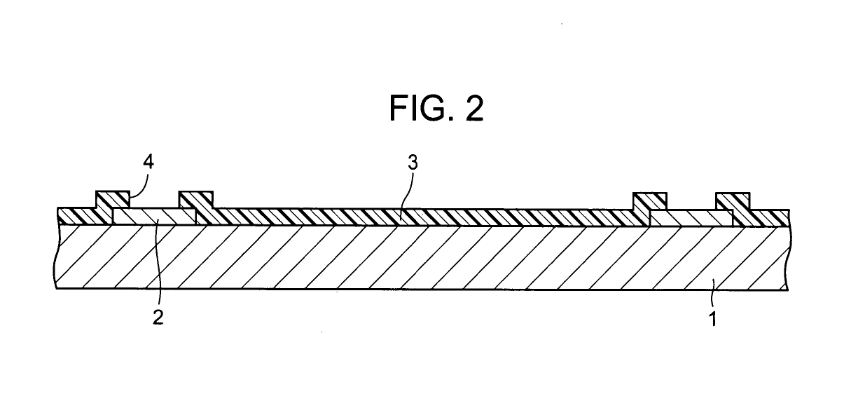

Next, an example of the semiconductor device manufacturing method will be explained. First, as illustrated in FIG. 2, provided on the silicon substrate 1 in the form of a wafer are the plurality of connection pads 2 made of an aluminum-base metal and the insulation film 3 made of an inorganic material like silicon oxide. The central portions of the connection pads 2 are exposed through the openings 4 formed in the insulation film 3. In this case, an integrated circuit (not shown) having a predetermined function is formed at an area in the silicon substrate 1 in the form of a wafer where each semiconductor device is to be formed, and each connection pad 2 is electrically connected to the integrated circuit formed at the corresponding area.

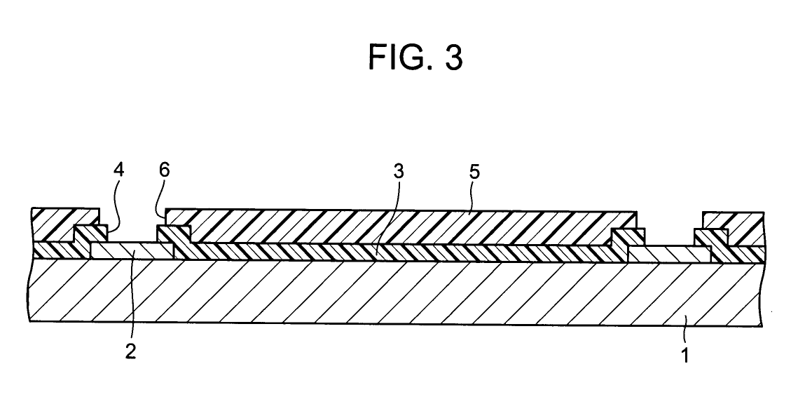

Subsequently, as illustrated in FIG. 3, the protective film 5 made of polyimide or PBO (Polyphenylene Benza Oxazole) is formed on the entire upper surface of the insulation film 3 including the upper surfaces of the connection pads 2 exposed through the openings 4 of the insulation film 3 by screen printing, spin coating or the like. Next, the openings 6 each of which is slightly larger than the opening 4 of the insulation film 3 are formed in the portions of the protective film 5 corresponding to the openings 4 of the insulation film 3 by photolithography.

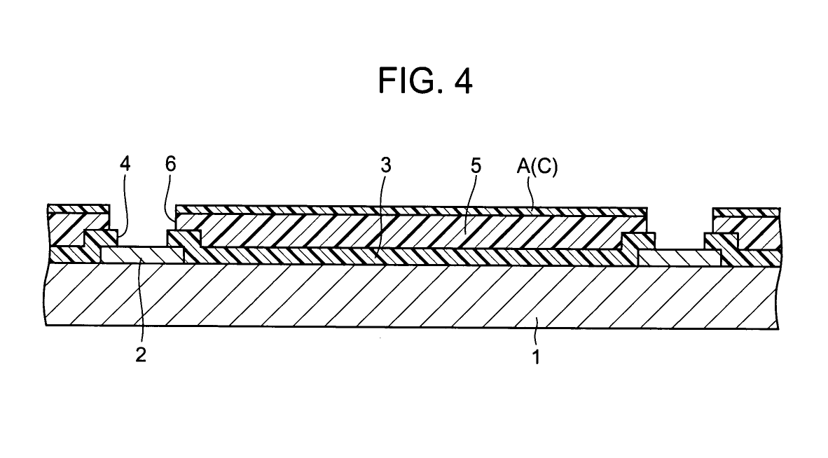

When the openings 6 are formed in the protective film 5 made of a resin of polyimide, PBO, or the like, a non-illustrated residue which is called scum and made of a resin of polyimide, PBO, or the like may remain on the upper surface of the connection pad 2 exposed through the opening 6 of the protective film 5. The residue is eliminated by oxygen plasma ashing. In this case, as illustrated in FIG. 4, the upper surface layer of the protective film 5 changes its property due to oxygen plasmas, so that the altered layer A is formed.

Next, a native oxide (not shown) formed on the upper surface of the connection pads 2, which is made of an aluminum-based metal and exposed through the openings 4 of the insulation film 3 and the openings 6 of the protective film 5 including the altered layer A, is eliminated by plasma etching using an inert gas like an argon gas. The plasma etching further alters the altered layer A, forming the altered layer C. Possible plasma etching schemes using the inert gas include reactive ion etching (RIE) of one cycle excitation or two cycle excitation, helicon wave excitation type reactive high density plasma, inductively coupled plasma (ICP) of two cycle excitation, ISM (Inductively Super Magnetron). Particularly, plasma etching using the ICP of two cycle excitation or ISM is preferable.

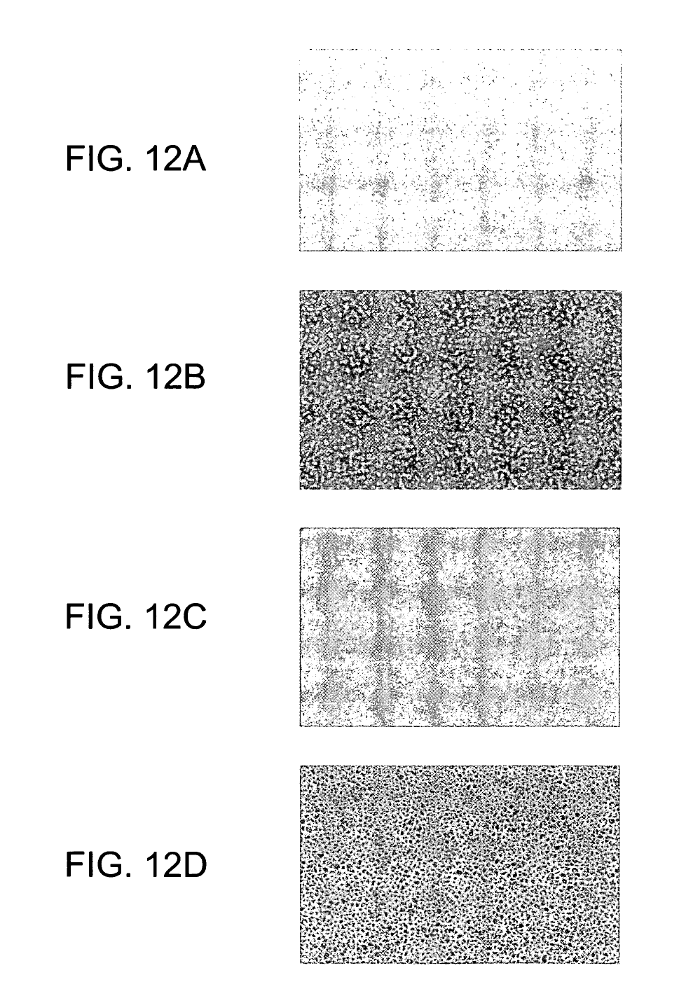

Referring to FIG. 12A which is an SEM (Scanning Electron Microscope) photograph of the upper surface of the protective film 5 illustrated in FIG. 3, the upper surface is almost flat, and no altered layer is formed. Next, referring to FIG. 12B which is an SEM photograph of the upper surface of the altered layer A, the upper surface has an undulated structure of 10 to 100 nm, and the altered layer A is formed. Subsequently, referring to FIG. 12C which is an SEM photograph of the upper surface of the altered layer C, the upper surface has a mesh-like structure which is rougher than the altered layer A, and the altered layer C is formed.

In this case, the diameter of the mesh of the altered layer C is 10 to 500 nm, the thickness of a mesh line is 10 to 200 nm, and a layer thickness is 10 to 1000 nm. Because elements constituting polyimide or PBO which is a material of the protective film 5 are carbon, oxygen, nitrogen, and hydrogen, elements constituting the altered layer C are carbon, oxygen, nitrogen, hydrogen, and an inert gas. In this case, the inert gas contained in the altered layer C is an argon gas in the case of a plasma etching process using an argon gas as an inert gas. Note that like the elements of the protective film 5, elements constituting the altered layer A are carbon, oxygen, nitrogen, and hydrogen.

In a case where argon ion etching undergone an ion gun scheme is performed instead of plasma etching using an argon gas to eliminate the native oxide on the upper surfaces of the connection pads 2, the altered layer B is formed instead of the altered layer C on the upper surface of the protective film 5. Referring to FIG. 12D which is an SEM photograph of the upper surface of the altered layer B, undulations observed in the altered layer A illustrated in FIG. 12B are reduced, so that the upper surface of the altered layer B becomes similar to the upper surface of the protective film 5 illustrated in FIG. 1 2A.

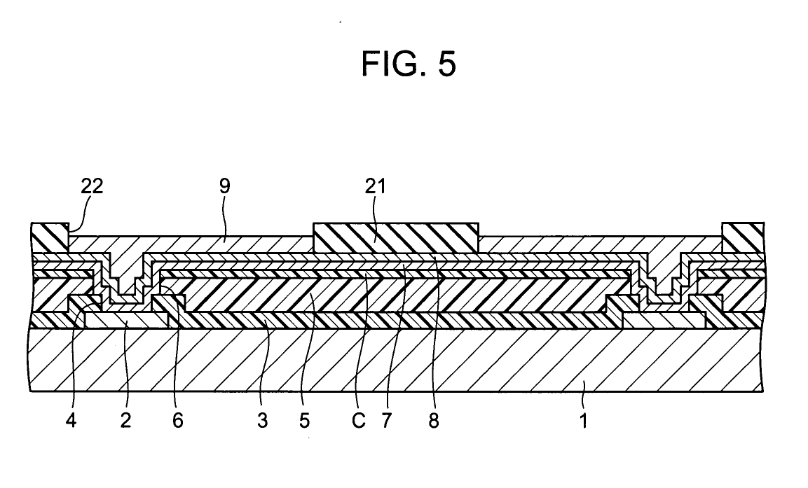

Next, as illustrated in FIG. 5, the first metallic base layer 7 made of titanium or chrome, and the second metallic base layer 8 made of copper are sequentially formed by spattering or the like on the entire surface of the altered layer C including the upper surfaces of the connection pads 2 exposed through the openings 4 of the insulation film 3 and the openings 6 of the protective film 5 including the altered layer C. In this case, because the first metallic base layer 7 is formed on the upper surface of the altered layer C, the adhesion of the interface therebetween is strong as will be discussed later. The metallic base layers may be one layer which has a bonding capability and a barrier capability.

Subsequently, a plating resist film 21 is patterned on the upper surface of the second metallic base layer 8 by patterning. In this case, an opening 22 is formed in that portion of the plating resist film 21 which corresponds to an area where the wiring 9 is to be formed. Next, electroplating with the first and second metallic base layers 7, 8 functioning as plating current paths forms the wire 9 on the upper surface of the second metallic base layer 8 in the opening 22 of the plating resist film 21. The plating resist film 21 is then removed. It is possible to form a wiring comprised of only a metallic base layer by forming the metallic base layer thickly.

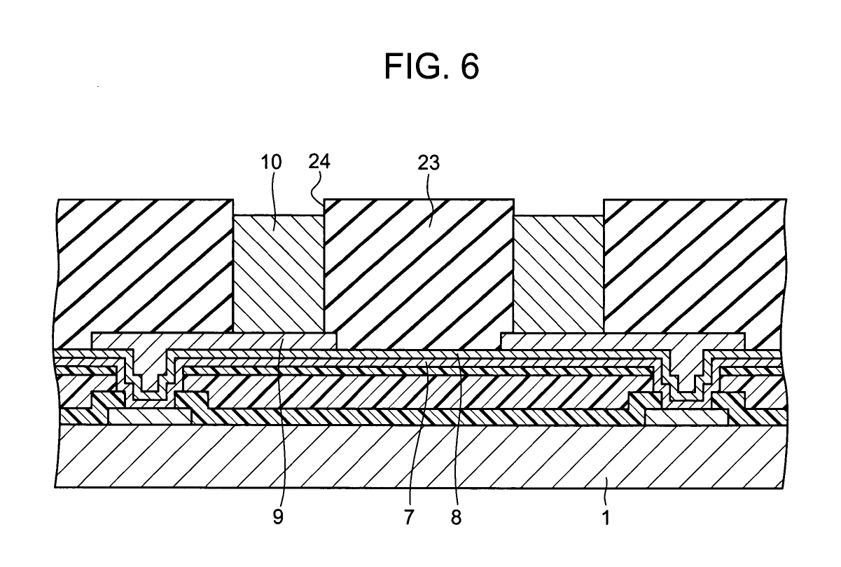

Next, as illustrated in FIG. 6, a plating resist film 23 is patterned on the upper surface of the second metallic base layer 8 including the wiring 9 by patterning. In this case, openings 24 are formed in portions of the plating resist film 23 corresponding to areas where the columnar electrodes 10 are to be formed. The columnar electrodes 10 are formed on the upper surfaces of connection pads of the wiring 9 in the openings 24 of the plating resist film 23 by performing copper electroplating with the first and second metallic base layers 7, 8 functioning as plating current paths.

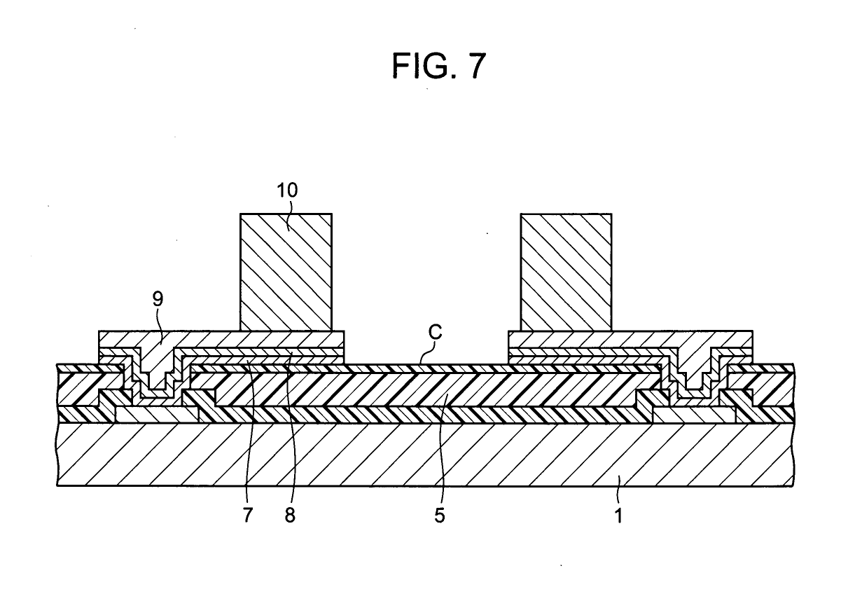

Subsequently, the plating resist film 23 is removed, and unnecessary portions of the first and second metallic base layers 7, 8 are eliminated by etching with the wiring 9 serving as a mask. As a result, the first and second metallic base layers 7, 8 remain only under the wiring 9 as illustrated in FIG. 7.

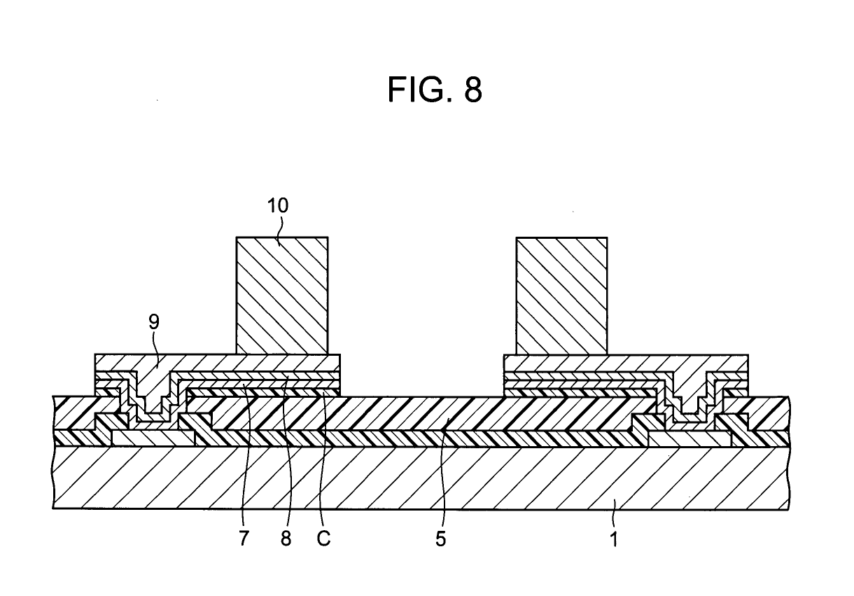

In this state, the altered layer C is formed on the upper surface of the protective film 5 at an area other than the area that underlies the first metallic base layer 7. Because the altered layer C is electrically conductive, if the altered layer C is present in this area, the wiring 9 is short-circuited. Accordingly, the portion of the altered layer C in the area other than the area underlying the first metallic base layer 7 is eliminated by oxygen plasma ashing, leaving the altered layer C only under the first metallic base layer 7 as illustrated in FIG. 8.

In this case, an ICP (Inductively Coupled Plasma) type plasma ashing device was used, and oxygen plasma ashing was performed on one wafer under conditions of oxygen amount of 200 to 500 sccm, plasma power of 500 to 1000 W, pressure of 20 to 133 Pa, stage temperature of 40 to 80° C., and process time of 10 to 60 sec.

The conditions resulted in over-ashing, so that a part of an area of the upper surface of the protective film 5 uncovered by the first metallic base layer 7 was eliminated, and the portion of the altered layer C in the area other than the area underlying the first metallic base layer 7 was completely eliminated. In this case, the upper surface layer of the protective film 5 in the area other than the area underlying the first metallic base layer 7 changed its property due to oxygen plasmas, forming the altered layer A, which had a resistance high enough to suppress a leak current or short-circuiting, because the altered layer A had a sufficient resistivity.

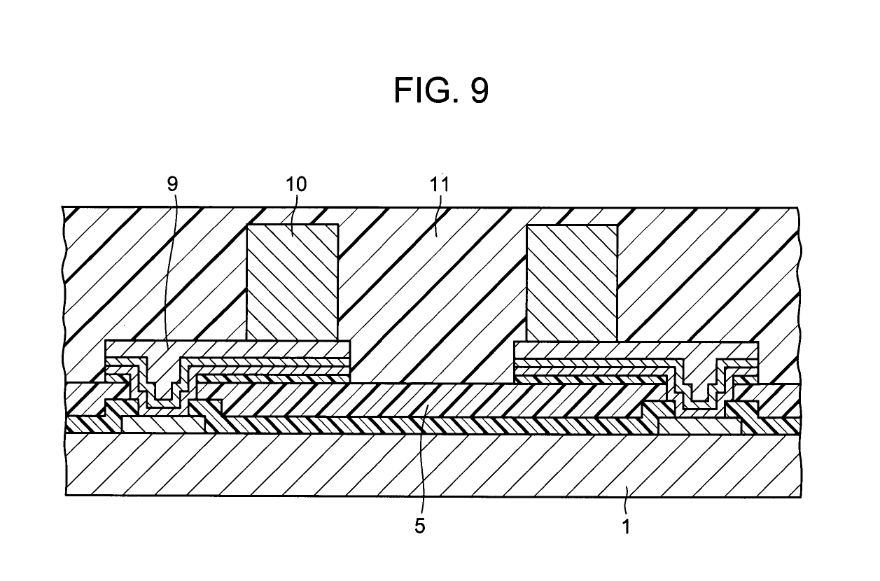

Next, as illustrated in FIG. 9, the sealing film 11 made of an epoxy-based resin or the like is formed on the entire surface of the protective film 5 including the columnar electrodes 10 and the wiring 9 by screen printing or spin coating in such a way that the thickness of the sealing film 9 becomes larger than the height of the columnar electrode 10. Therefore, the upper surfaces of the columnar electrodes 10 are covered by the sealing film 11 in this state.

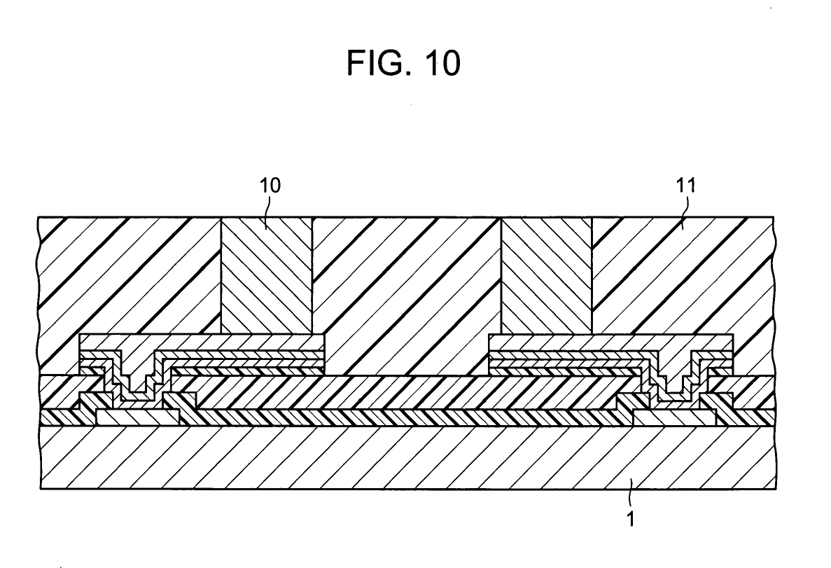

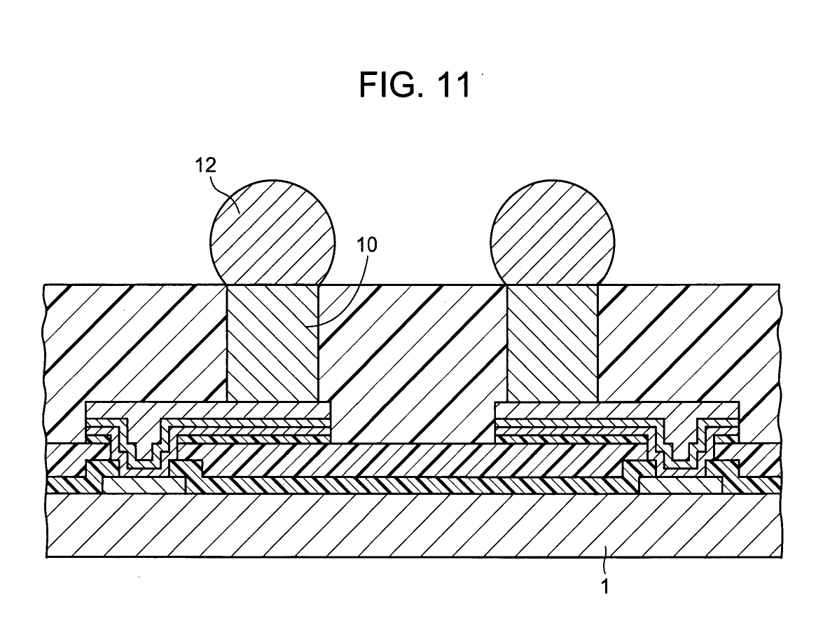

Subsequently, the sealing film 11 and the upper surface sides of the columnar electrodes 10 are appropriately polished, so that the upper surfaces of the columnar electrodes 10 are exposed as illustrated in FIG. 10, and the upper surface of the sealing film 11 and the upper surfaces of the exposed columnar electrodes 10 are planarized. As illustrated in FIG. 11, the solder balls 12 are formed on the upper surfaces of the columnar electrodes 10. A plurality of semiconductor devices illustrated in FIG. 1 are obtained through a dicing processes.

In the semiconductor device obtained in this manner, because the altered layer C with a mesh-like structure is formed, not the altered layer B, on the upper surface side of the protective film 5 made of polyimide, PBO or the like, the adhesion of the altered layer C with the mesh-like structure with respect to the first metallic base layer 7 made of titanium, chrome or the like can be enhanced as explained below.

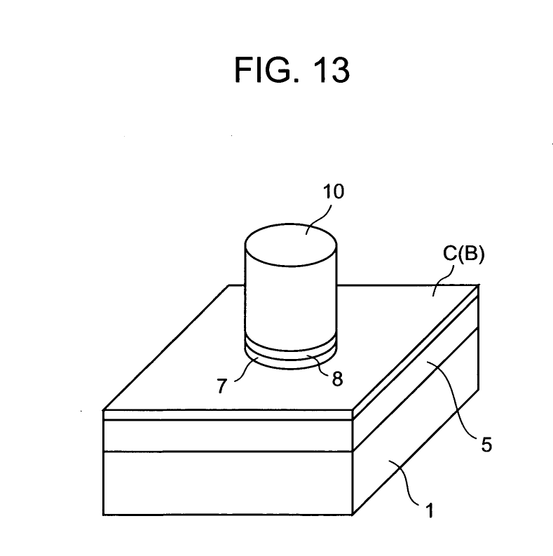

An explanation will now be given of a shear intensity test by a pressure cooker test (PCT) of a semiconductor device manufactured by the foregoing manufacturing method. First, as illustrated in FIG. 13, a semiconductor device of the invention formed by the manufacturing method was prepared. The semiconductor device of the invention was structured in such a way that the protective film 5 of polyimide was formed on the silicon substrate 1, the altered layer C was formed on the upper surface of the protective film 5, and the first metallic base layer 7 made of titanium, the second metallic base layer 8 made of copper and the columnar electrode 10 made of copper, all having circular planes were formed on the upper surface of the altered layer C. As illustrated in FIG. 13, one columnar electrode 10 was formed on the semiconductor device of the invention. For comparison, a comparative semiconductor device structured in the same way as the semiconductor of the invention illustrated in FIG. 13, but having the altered layer B formed on the upper surface of the protective film 5 was prepared.

With the silicon substrates 1 fixed, a shear measuring jig (not shown) was pressed against the sides of the columnar electrodes 10 of each of the semiconductor device of the invention and the comparative semiconductor device, and the strength (g) when the first metallic base layer 7 was removed from the altered layer C (or B) was acquired. In this case, given that the shear strengths of the semiconductor device of the invention and the comparative semiconductor device prior to an environmental test were 1, shear strengths after the semiconductor devices were left for 500 hours with the PCT saturated (temperature 121° C., humidity 100% Rh, two pressure) were obtained.

In the case of the comparative semiconductor device, suppose that the shear strength prior to an environmental test was set to 1, the shear strength after the comparative semiconductor device was left for 500 hours under the saturation of the PCT dropped to 0.1. In contrast, in the case of the semiconductor device of the invention, suppose that the shear strength prior to an environmental test was set to 1, the shear strength after the semiconductor device was left for 500 hours under the saturation of the PCT dropped to 0.68. The semiconductor device of the invention had a shear strength 6.8 times as much as that of the comparative semiconductor device. It follows that interface adhesion was enhanced.

The present invention is not limited to a semiconductor device which is called CSP, and can be applied to one like a conventional example in which a plurality of connection pads, an insulation film, and a protective film are formed on a semiconductor substrate, the connection pads are exposed through openings provided in the insulation film and the protective film, and first and second metallic base layers and bump electrodes are formed on the upper surfaces of the connection pads and the upper surface of the protective film in the vicinity of the connection pads.

According to the invention, forming the altered layer with a mesh-like structure different from the altered layer B on the upper surface side of the protective film can enhance the adhesion of altered layer with the mesh-like structure with respect to a metallic base layer.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2005-275631 filed on Sep. 22, 2005 and including specification, claims, drawings and summary. The disclosure of the above Japanese Patent Application is incorporated herein by reference in its entirety.

What is claimed is:

1. A semiconductor device comprising:
a semiconductor substrate having a plurality of connection pads on an upper surface thereof;
a protective film made of a resin which is provided on the semiconductor substrate, and has openings at those portions to which the respective connection pads correspond;
an altered layer having a mesh-like structure formed on an upper surface of the protective film; and
a metallic layer provided on upper surfaces of the connection pads and an upper surfaces of the altered layer.

2. The semiconductor device according to claim 1, wherein the protective film is formed of a resin containing carbon, oxygen, nitrogen, and hydrogen.

3. The semiconductor device according to claim 2, wherein the altered layer contains carbon, oxygen, nitrogen, hydrogen, and argon.

4. The semiconductor device according to claim 1, wherein the altered layer having the mesh-like structure has a mesh diameter of 10 to 500 nm, a mesh line thickness of 10 to 200 nm, and an entire thickness of the layer of 10 to 1000 nm.

5. The semiconductor device according to claim 1, wherein a wiring is provided on the metallic layer.

6. The semiconductor device according to claim 5, wherein a columnar electrode is provided on the connection pad of the wiring.

7. The semiconductor device according to claim 6, wherein a sealing film is formed around the columnar electrode, and a solder ball is provided on the columnar electrode.

8. A semiconductor device manufacturing method comprising:
a step of forming a protective film made of a resin on a semiconductor substrate having a plurality of connection pads on an upper surface thereof in such a way that the protective film has openings at those portions to which the connection pads correspond;
a protective film residue elimination step of eliminating a residue of the protective film remaining on upper surfaces of the connection pads exposed through the openings of the protective film by an oxygen plasma ashing; an oxide film elimination step of eliminating an oxide film formed on the upper surfaces of the connection pads exposed through the openings of the protective film by a plasma etching with an inert gas;
a metallic film formation step of forming a metallic film on the upper surfaces of the connection pads exposed through the openings of the protective film and an upper surface of the protective film; and
a protective film upper surface layer elimination step of eliminating an upper surface layer of the protective film in an area other than an area underlying the metallic layer by an oxygen plasma ashing,
wherein a first altered layer formed on the upper surface of the protective film in the protective film residue elimination step is altered to a second altered layer having a larger surface roughness than that of the first altered layer in the oxide film elimination step, thereby improving reduced adhesion between the metallic film formed on the second altered layer formed on the upper surface of the protective film in the metallic film formation step and the protective film.

9. The semiconductor device manufacturing method according to claim 8, wherein the protective film upper surface elimination step eliminates the upper surface of the protective film deeper than a thickness of the second altered layer altered in the oxide film elimination step from the first altered layer formed on the upper surface of the protective film in the protective film residue elimination step.

10. The semiconductor device manufacturing method according to claim 8, wherein the second altered layer has a mesh-like structure.

11. The semiconductor device manufacturing method according to claim 10, wherein the altered layer with the mesh-like structure has a mesh diameter of 10 to 50 nm, a mesh line thickness of 10 to 200 nm, and an entire thickness of the layer of 10 to 1000 nm.

12. The semiconductor device manufacturing method according to claim 8, wherein the protective film is formed of a resin containing carbon, oxygen, nitrogen, and hydrogen.

13. The semiconductor device manufacturing method according to claim 12, wherein the inert gas is an argon gas, and the second altered layer contains carbon, oxygen, nitrogen, hydrogen, and argon.
